(19) United States
(12) Patent Application Publication
(10) Pub. No.: US 2013/0270629 A1
(43) Pub. Date: Oct. 17, 2013

(54) SEMICONDUCTOR DEVICE HAVING VERTICAL TRANSISTOR

(71) Applicant: ELPIDA MEMORY, INC., Tokyo (JP)

(72) Inventor: Yoshinori IKEBUCHI, Tokyo (JP)

(73) Assignee: ELPIDA MEMORY, INC., Tokyo (JP)

(21) Appl. No.: 13/845,743

(22) Filed: Mar. 18, 2013

(30) Foreign Application Priority Data
Apr. 12, 2012 (JP) 2012-091037

(51) Int. Cl. H01L 27/088

(52) U.S. Cl. CPC H01L 27/088
USPC 257/329

(57) ABSTRACT

Disclosed herein is a device that includes: a semiconductor substrate; a first semiconductor pillar having a side surface that is substantially perpendicular to a main surface of the semiconductor substrate; an insulator pillar having a side surface that is substantially perpendicular to the main surface of the semiconductor substrate and a top surface that is substantially parallel to the main surface of the semiconductor substrate; a first gate electrode covering the side surface of the first semiconductor pillar with intervention of a first gate insulation film; an extended gate electrode covering the side surface of the insulator pillar, the extended gate electrode being configured integrally with the first gate electrode; and a conductive film formed on the top surface of the insulator pillar, the conductive film being in contact with the extended gate electrode in a position above the top surface of the insulator pillar.

### BACKGROUND OF THE INVENTION

1. Field of the Invention

The present invention relates to a semiconductor device and a method for manufacturing the same, and more particularly to a semiconductor device having a vertical transistor and a method for manufacturing the same.

2. Description of Related Art

The chip sizes of semiconductor devices, or memory devices in particular, have been reduced year by year from the viewpoint of cost reduction. More and more dynamic random access memories (DRAMs) are then adopting vertical transistors having a 4F² structure for their cell transistors. Conventional planar transistors continue being used for peripheral circuit transistors because a demand for the miniaturization of such transistors is not as high as with cell transistors. However, cell transistors and peripheral circuit transistors having different structures, the number of processes increases significantly. The adoption of vertical transistors with a 4F² structure as peripheral circuit transistors has thus been considered lately (see Japanese Patent Application Laid-Open No. 2008-288391).

As described in Japanese Patent Application Laid-Open No. 2008-288391, vertical transistors arranged in peripheral circuits have two adjoining semiconductor pillars. One of the semiconductor pillars is used as a channel. Impurity diffusion layers are formed both on the upper and lower portions of the semiconductor pillar. The side surfaces of the semiconductor pillar are covered with a gate electrode via a gate insulation film. The other semiconductor pillar is a dummy semiconductor pillar for extending the length of the gate electrode in a lateral direction. The extended portion is utilized to form a gate contact plug.

The gate electrode of a vertical transistor is formed by forming a conductive film covering the entire active region and etching back the conductive film after formation of the two semiconductor pillars. Such a method has the advantages that the gate electrode can be easily formed without using lithography, and that it is suitable for miniaturization because the gate electrode can be thinly formed on the sidewalls of the semiconductor pillar.

The foregoing forming method has the problem, however, that the resulting gate electrode has high wiring resistance. That is, for low wiring resistance, the gate electrode is preferably made of a low-resistivity metal material such as tungsten. However, it is difficult to uniformly form the top surface of such a gate electrode by etch-back since metal materials have high crystallinity. The gate electrode to be formed by etch-back therefore needs to be made of a silicon film having high etch-back controllability (an impurity-doped silicon film formed by CVD). This type of silicon film has a resistivity higher than those of metal materials by approximately two digits, and thus increases the wiring resistance of the gate electrode.

The advantage that the gate electrode can be thinly formed on the sidewalls of the semiconductor pillar is, in a sense, a disadvantage contributing to higher wiring resistance. In conventional vertical transistors, the gate electrode needs to be made of a silicon film having high resistivity as described above. Besides, the silicon film is formed with an extremely small thickness. As a result, the wiring resistance of the gate electrode has been extremely high.

### SUMMARY

In one embodiment, there is provided a semiconductor device that includes: a semiconductor substrate having a main surface; a first semiconductor pillar having a side surface that is substantially perpendicular to the main surface of the semiconductor substrate; an insulator pillar having a side surface that is substantially perpendicular to the main surface of the semiconductor substrate and a top surface that is substantially parallel to the main surface of the semiconductor substrate; a first gate electrode covering the side surface of the first semiconductor pillar with an intervention of a first gate insulation film; an extended gate electrode covering the side surface of the insulator pillar, the extended gate electrode being contacted with the first gate electrode; and a conductive film formed on the top surface of the insulator pillar, the conductive film being in contact with the extended gate electrode in a position above the top surface of the insulator pillar.

In another embodiment, there is provided a semiconductor device that includes: a semiconductor substrate having a main surface; a plurality of first semiconductor pillars arranged in a first direction, each of the first semiconductor pillars having a side surface that is substantially perpendicular to the main surface of the semiconductor substrate; a plurality of second semiconductor pillars arranged in the first direction, each of the second semiconductor pillars having a side surface that is substantially perpendicular to the main surface of the semiconductor substrate; a plurality of insulator pillars each arranged between an associated one of the first semiconductor pillars and an associated one of the second semiconductor pillars, each of the insulator pillars having a side surface that is substantially perpendicular to the main surface of the semiconductor substrate and a top surface that is substantially parallel to the main surface of the semiconductor substrate; a plurality of first gate electrodes each covering the side surface of each of the first semiconductor pillars with an intervention of a first gate insulation film; a plurality of second gate electrodes each covering the side surface of each of the second semiconductor pillars with an intervention of a second gate insulation film; a plurality of extended gate electrodes each covering the side surface of each of the insulator pillars, the extended gate electrode being contacted with the first and second gate electrodes; a plurality of conductive films each formed on the top surface of an associated one of the insulator pillars, the conductive films being in contact with the extended gate electrode in a position above the top surface of each of the insulator pillars; a plurality of first upper diffusion layers each formed in contact with an upper portion of an associated one of the first semiconductor pillars; a plurality of second upper diffusion layers each formed in contact with an upper portion of an associated one of the second semiconductor pillars; a first wiring extending in the first direction and connected in common to the first upper diffusion layers; a second wiring extending in the first direction and connected in common to the second upper diffusion layers; a third wiring connected between the first and second wirings; and a fourth wiring extending in the first direction and connected in common to the conductive films.

According to the present invention, the conductive film formed on the top surface of the insulator pillar functions as a part of the gate electrode. This can reduce the wiring resistance of the gate electrode.

### BRIEF DESCRIPTION OF THE DRAWINGS

FIG. 1 is a schematic sectional view of a semiconductor device 1 according to a first embodiment of the present invention;

FIGS. 2A, 2B, 3A, and 3B are plan views showing the semiconductor device 1 corresponding to lines A-A, B-B, C-C, and D-D of FIG. 1, respectively, FIG. 2A also showing a planar arrangement of upper diffusion layer contact plugs 23, a gate contact plug 24, and a wiring pattern 25 shown in FIG. 1;

FIGS. 4A and 4B to 9A and 9B and FIG. 10 are process diagrams for explaining the method for manufacturing the semiconductor device 1 shown in FIG. 1;

FIG. 11 is a plan view showing a semiconductor device 1 according to a second embodiment of the present invention;

FIGS. 12 and 13 are plan views showing a semiconductor device 1 according to a third embodiment of the present invention; and

FIGS. 14A and 14B are plan views showing a semiconductor device 1 according to a fourth embodiment of the present invention.

### DETAILED DESCRIPTION OF THE EMBODIMENTS

Preferred embodiments of the present invention will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

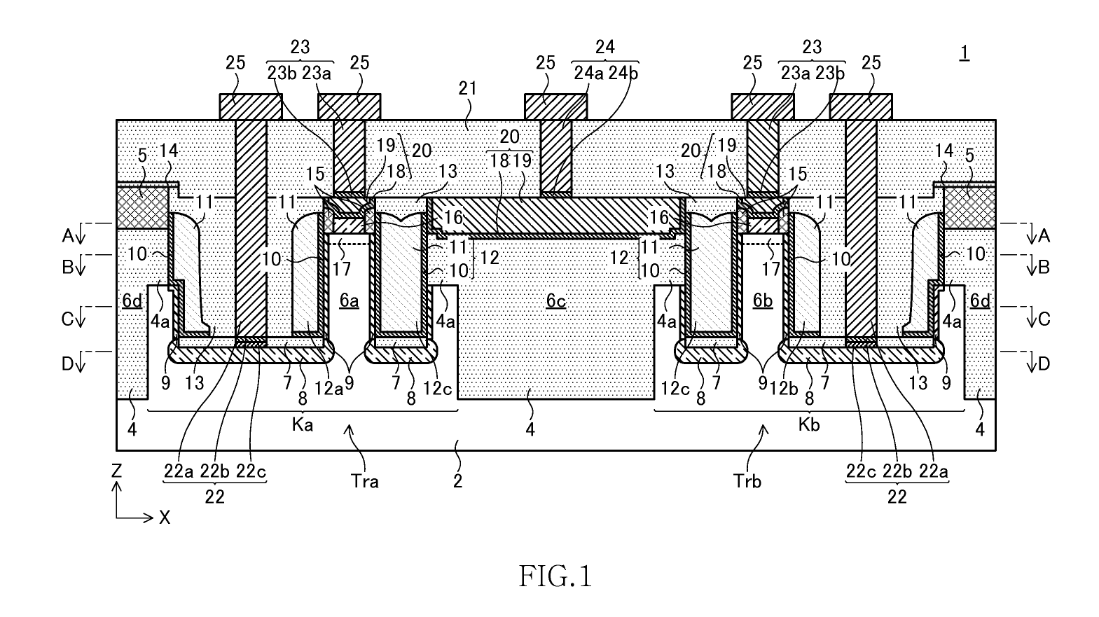

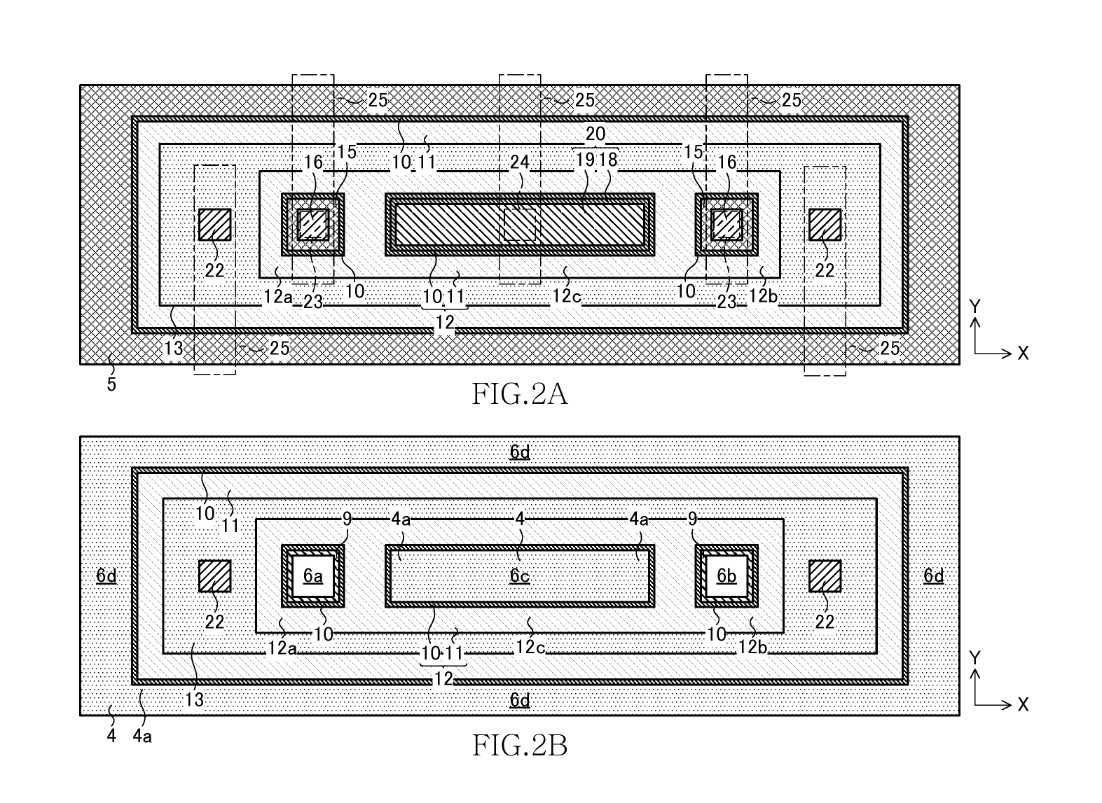

Referring now to FIGS. 1, 2A, 2B, 3A, and 3B, the semiconductor device 1 according to the first embodiment of the present invention includes a semiconductor (silicon) substrate 2. A silicon oxide film 4 constituting element isolation regions according to a shallow trench isolation (STI) method is embedded in the main surface of the semiconductor substrate 2. A first active region Ka and a second active region Kb adjoining each other in an X direction are defined on the main surface of the semiconductor substrate 2 by the silicon oxide film 4. Part of the silicon oxide film 4 (silicon oxide films 4a shown in FIGS. 1 and 2B) is formed to protrude out on the first and second active regions Ka and Kb.

In the present embodiment, as will be described in detail later, the first and second active regions Ka and Kb each include a vertical transistor (transistor having a channel region formed in a Z direction). Hereinafter, the vertical transistor formed in the first active region Ka will be referred to as a transistor Tra, and the vertical transistor formed in the second active region Kb as a transistor Trb.

The first and second active regions Ka and Kb include first and second semiconductor pillars (silicon pillars) 6a and 6b, respectively. The first and second semiconductor pillars 6a and 6b constitute the channel regions of the transistors Tra and Trb, respectively.

An insulator pillar 6c is formed in the element isolation region lying between the first active region Ka and the second active region Kb. The insulator pillar 6c includes silicon oxide films 4a protruding out on the respective first and second active regions Ka and Kb. Accordingly, the semiconductor substrate 2 is exposed in the lower portions of the side surfaces of the insulator pillar 6c at the sides of the first and second active regions Ka and Kb. The entire top surface of the insulator pillar 6c is made of an insulator (silicon oxide film 4).

An insulator pillar 6d is formed in the element isolation region surrounding the first and second active regions Ka and Kb. The insulator pillar 6d also includes silicon oxide films 4a protruding out on the respective first and second active regions Ka and Kb. Accordingly, the semiconductor substrate 2 is exposed in the lower portions of the side surfaces of the insulator pillar 6d at the sides of the first and second active regions Ka and Kb. The entire top surface of the insulator pillar 6d is made of an insulator (silicon oxide film 4). In a plan view, the insulator pillar 6d has a tube-like shape. The first and second active regions Ka and Kb are arranged in the area surrounded by the insulator pillar 6d of tube-like shape. As shown in FIG. 1, a silicon nitride film 5 is formed on the top surface of the insulator pillar 6d. The silicon nitride film 5 is the remainder of a mask insulation film used in pillar formation.

Lower diffusion layers 8 are formed on the surfaces (bottoms) of the semiconductor substrate 2 surrounded by the pillars 6a to 6d. The lower diffusion layers 8 each constitute either one of a source and a drain of the corresponding vertical transistor. The top surfaces of the lower diffusion layers 8 are covered with a silicon oxide film 7.

The side surfaces of the first and second semiconductor pillars 6a and 6b are thermally oxidized to form a gate insulation film 9. As shown in FIG. 1, a gate insulation film 9 is also formed on the surfaces of the semiconductor substrate 2 exposed in the side surfaces of the insulator pillars 6c and 6d. However, the latter is formed solely due to manufacturing reasons, and will not function as the gate insulation films of the transistors Tra and Trb.

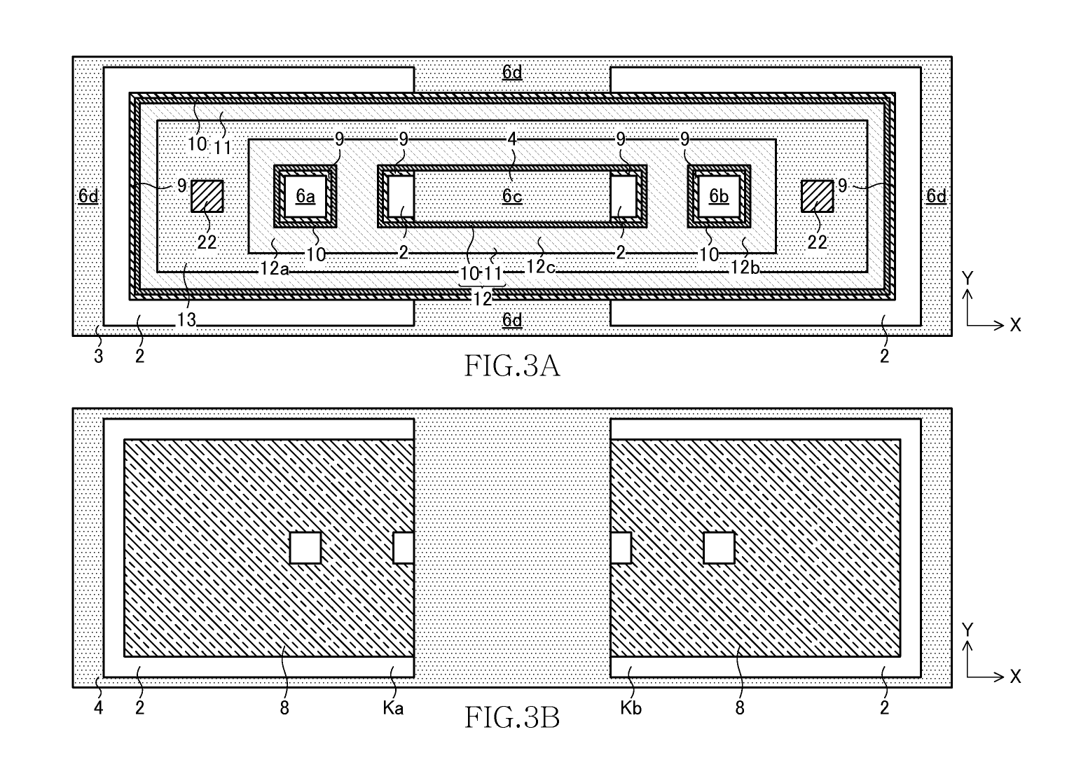

A gate electrode 12 is formed on the side surfaces of the first and second semiconductor pillars 6a and 6b and the insulator pillar 6c. The gate electrode 12 is a sidewall conductive film having a structure that a polysilicon film 11 is stacked on a barrier layer 10 (second barrier layer) which is a metal film. As shown in FIGS. 2A, 2B, and 3A, the gate electrode 12 is integrally formed to surround the pillars 6a to 6c. As shown in FIG. 1, a gate electrode 12 is also formed on the side surfaces of the insulator pillar 6d. However, the latter is formed solely due to manufacturing reasons, and will not function as the gate electrodes of the transistors Tra and Trb.

The gate electrode 12 includes a portion formed on the side surfaces of the first semiconductor pillar 6a (first gate electrode 12a), a portion formed on the side surfaces of the second semiconductor pillar 6b (second gate electrode 12b), and a portion formed on the side surfaces of the insulator pillar 6c (extended gate electrode 12c). The first gate electrode 12a and the extended gate electrode 12c are in contact with each other at their side surfaces. The second gate electrode 12b and the extended gate electrode 12c are in contact with each other at their side surfaces. Accordingly, the three partial electrodes 12a to 12c of the gate electrode 12 are thereby integrated into a single gate electrode.

A conductive film 20 is formed on the top surface of the insulator pillar 6c. The conductive film 20 has a structure that a tungsten film 19 is stacked on a barrier layer 18 (first barrier layer) which is a metal film. The conductive film 20 covers the entire top surface of the insulator pillar 6c. As shown in FIG. 2A, at the entire circumference of the top surface of the insulator pillar 6c, the conductive film 20 is in contact with the gate electrode 12 (extended gate electrode 12c) formed on the side surfaces of the insulator pillar 6c. As a result, the gate electrode and the conductive film 20 are electrically short-circuited.

Lightly doped drain (LDD) diffusion layers 17 are formed at the top ends of the respective first and second semiconductor pillars 6a and 6b. Upper diffusion layers 16 each constituting the other of the source and drain of the corresponding vertical transistor are further formed on the top surfaces of the respective LDD diffusion layers 17. The side surfaces of the upper diffusion layers 16 are covered with a sidewall-like silicon nitride film 15, whereby the gate electrode 12 is insulated from the upper diffusion layers 16. Like the top surface of the insulator pillar 6c, a conductive film 20 including a barrier layer 18 and a tungsten layer 19 is formed on the top surfaces of the upper diffusion layers 16.

A silicon oxide film for covering the configurations described so far is formed on the main surface of the semiconductor substrate 2. As shown in FIG. 1, the silicon oxide film includes interlayer insulation films 13 and 21 and a mask silicon oxide film 14 which is used in the process of manufacturing the semiconductor device 1 to be described later. The interlayer insulation film 13 is formed to have a top surface at the same height as that of the top surface of the conductive film 20. The interlayer insulation film 13 covers the entire gate electrode 12. The interlayer insulation film 21 is formed on the top surface of the interlayer insulation film 13. The mask silicon oxide film 14 is formed on the top surface of the silicon nitride film 5 remaining on the top surface of the insulator pillar 6d.

Various traces of the wiring pattern 25 are formed on the top surface of the interlayer insulation film 21. Each trace of the wiring pattern 25 is electrically connected to any one of the lower diffusion layers 8, the upper diffusion layers 16, and the gate electrode 12 via a contact plug which runs through the silicon oxide film(s).

More specifically, the lower diffusion layers 8 and the wiring pattern 25 are electrically connected to each other via lower diffusion layer contact plugs 22. As shown in FIG. 2A, the lower diffusion layer contact plugs 22 are formed in the first and second active regions Ka and Kb on a one-on-one basis, in respective areas where none of the pillars 6a to 6d and the gate electrode 12 is formed. As shown in FIG. 1, the lower diffusion layer contact plugs 22 run through the interlayer insulation films 13 and 21 and the silicon oxide film 7, and make contact with the corresponding lower diffusion layers 8 at the bottom. As shown in FIG. 1, the lower diffusion layer contact plugs 22 are a stacked film of a tungsten film 22a, a barrier layer 22b, and a cobalt silicide film 22c. The configuration of the stacked film will be described again in detail when a method for manufacturing the semiconductor device 1 is described later.

The upper diffusion layers 16 and the wiring pattern 25 are electrically connected to each other via upper diffusion layer contact plugs 23. As shown in FIG. 2A, the upper diffusion layer contact plugs 23 are formed in positions overlapping with the respective first and second semiconductor pillars 6a and 6b when seen in a plan view on a one-on-one basis. As shown in FIG. 1, the upper diffusion layer contact plugs 23 run through the interlayer insulation film 21 and make contact with the corresponding conductive films 20 at the bottom. The upper diffusion layer contract plugs 23 are electrically connected to the upper diffusion layer 16 through the conductive films 20. As shown in FIG. 1, the upper diffusion layer contact plugs 23 are a stacked film of a tungsten film 23a and a barrier layer 23b. The configuration of the stacked film will also be described in detail when the method for manufacturing the semiconductor device 1 is described later.

The gate electrode 12 and the wiring pattern 25 are electrically connected to each other via a gate contact plug 24. As shown in FIG. 2A, only one gate contact plug 24 is formed in a position overlapping with the insulator pillar 6c when seen in a plan view. Note that while the gate contact plug 24 here is formed in the position overlapping with the insulator pillar 6c, the gate contact plug 24 may be formed in a position overlapping with the gate electrode 12 (extended gate electrode 12c) formed around the insulator pillar 6c. As shown in FIG. 1, the gate contact plug 24 runs through the interlayer insulation film 21 and makes contact with the corresponding conductive film 20 at the bottom. The gate contact plug 24 is electrically connected to the gate electrode 12 through the conductive film 20. As shown in FIG. 1, the gate contact plug 24 is a stacked film of a tungsten film 24a and a barrier layer 24b. The configuration of the stacked film will also be described in detail when the method for manufacturing the semiconductor device 1 is described later.

An operation of the semiconductor device 1 having the foregoing configuration will be described. As mentioned above, the semiconductor device 1 includes the transistors Tra and Trb in the first and second active regions Ka and Kb, respectively. The channels of the transistors Tra and Trb are formed inside the first and second semiconductor pillars 6a and 6b, respectively.

Since the transistors Tra and Trb have the integrated gate electrode 12, the transistors Tra and Trb are not individually controllable but operate simultaneously. Specifically, if the potential of the gate electrode 12 is activated through the gate contact plug 24, channels are formed in both the first and second semiconductor pillars 6a and 6b. As a result, the upper diffusion layers 16 and the lower diffusion layers 8 in the first and second active regions Ka and Kb become conducting, whereby the transistors Tra and Trb are both turned on. On the other hand, if the potential of the gate electrode 12 is deactivated through the wiring pattern 25, no channel is formed in the first and second semiconductor pillars 6a and 6b. As a result, the upper diffusion layers 16 and the lower diffusion layers 8 in the first and second active regions Ka and Kb are electrically disconnected, whereby the transistors Tra and Trb are both turned off.

As has been described, according to the semiconductor device 1 of the present embodiment, the conductive film 20 electrically connected to the gate electrode 12 can function as a part of the gate electrodes of the transistors Tra and Trb. The wiring resistances of the gate electrodes can thus be reduced as compared to when the conductive film 20 is not used. Since the conductive film 20 is made of a metal material, the wiring resistances of the gate electrodes can be made even smaller.

Since the conductive film 20 is formed on the top surface of the insulator pillar 6c, the gate contact plug 24 can be formed on the top surface of the conductive film 20 aside from the top surface of the extended gate electrode 12c (the portion of the gate electrode 12 formed on the side surfaces of the insulator pillar 6c). In other words, the forming area of the gate contact plug 24 is extended to the top surface of the conductive film 20, which facilitates position control when making a contact hole (contact hole 46 to be described later) for the gate contact plug 24. As a result, the probability of a loose connection between the gate electrode 12 and the gate contact plug 24 decreases. The probability of a phenomenon in which the hole-making position falls outside the gate electrode 12 and the contact hole 46 reaches one of the lower diffusion layers 8 to cause direct conduction between the gate contact plug 24 and the lower diffusion layer 8, also decreases. These improve the yield ratio of the semiconductor device 1.

As shown in FIG. 2A, the entire bottom surface of the gate contact plug 24 can be put into contact with the conductive film 20 to increase the contact area between the gate contact plug 24 and the gate electrode 12. This can reduce the contact resistance between the gate contact plug 24 and the gate electrode 12.

In the semiconductor device 1 according to the present embodiment, the wiring distances between the gate contact plug 24 and the channel areas are greater than heretofore. However, since the conductive film 20 is made of a metal material (tungsten film 19), a delay of the signal passing through the longer wiring can be reduced as compared to when the conductive film 20 is made of the same polysilicon film as that of the gate electrode 12.

Next, the method for manufacturing the semiconductor device 1 according to the present embodiment will be described.

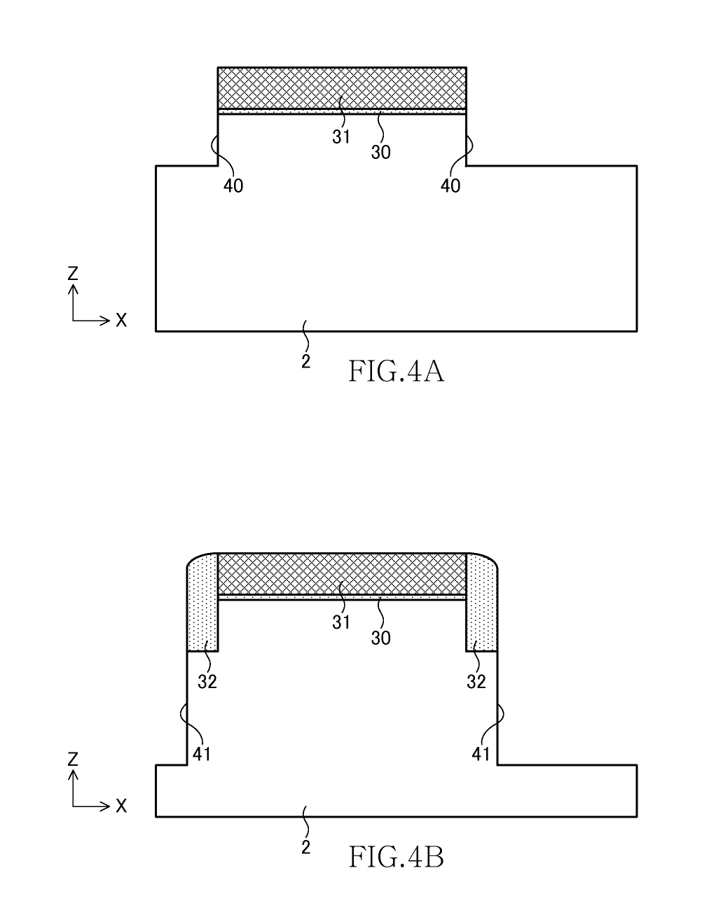

FIGS. 4A and 4B to 9A and 9B generally show only the left half (first active area Ka side) of the schematic sectional view of the semiconductor device shown in FIG. 1. The right half (second active area Kb side) has a similar configuration. With reference to the diagrams, the method for manufacturing the semiconductor device 1 will be described in detail below.

Initially, as shown in FIG. 4A, a 5-nm-thick pad oxide film (silicon oxide film) 30 and a 100-nm-thick silicon nitride film 31 are successively deposited on the entire top surface of a semiconductor substrate 2 which is a p-type monocrystalline silicon substrate. The silicon nitride film 31 is patterned to shapes somewhat narrower than active regions. With the patterned silicon nitride film 31 as a mask, dry etching is performed to form grooves 40 having a depth of approximately 80 nm in the main surface of the semiconductor substrate 2.

After the formation of the grooves 40, a silicon oxide film is deposited on the entire surface, followed by etch-back. As shown in FIG. 4B, a sidewall oxide film 32 is thereby formed along the inner walls of the grooves 40. With the silicon nitride film 31 and the sidewall oxide film 32 as a mask, the main surface of the semiconductor substrate 2 is further etched by approximately 350 nm to form grooves 41 having a depth of approximately 430 nm.

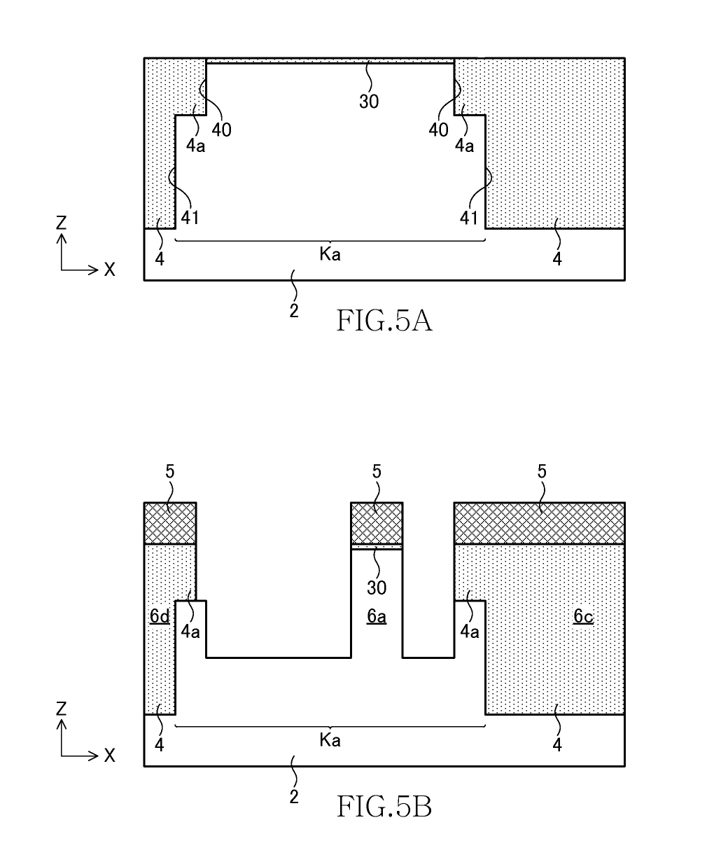

After the formation of the grooves 41, the sidewall oxide film 32 and the silicon nitride film 31 are removed in succession. As shown in FIG. 5A, a silicon oxide film 4 is then formed to fill the grooves 40 and 41 by a known STI method. Element isolation regions are completed by the steps so far, whereby the first and second active regions Ka and Kb are defined on the main surface of the semiconductor substrate 2. The areas where the sidewall oxide film 32 lies at the stage of FIG. 4B are filled with silicon oxide films 4a, a part of the silicon oxide film 4, to constitute the element isolation regions. The semiconductor substrate 2 remains below the silicon oxide films 4a to constitute the first and second active regions Ka and Kb.

Next, a 100-nm-thick silicon nitride film is formed on the entire surface. The silicon nitride film is etched by using a photolithographic technique and a dry etching technique to form a silicon nitride film 5 (mask insulation film). As shown in FIG. 5B, the silicon nitride film 5 is patterned to the shapes of the first and second silicon pillars 6a and 6b and the insulator pillars 6c and 6d. With the silicon nitride film 5 as a mask, the silicon and the silicon oxide film are etched to form the first and second semiconductor pillars 6a and 6b and the insulator pillars 6c and 6d.

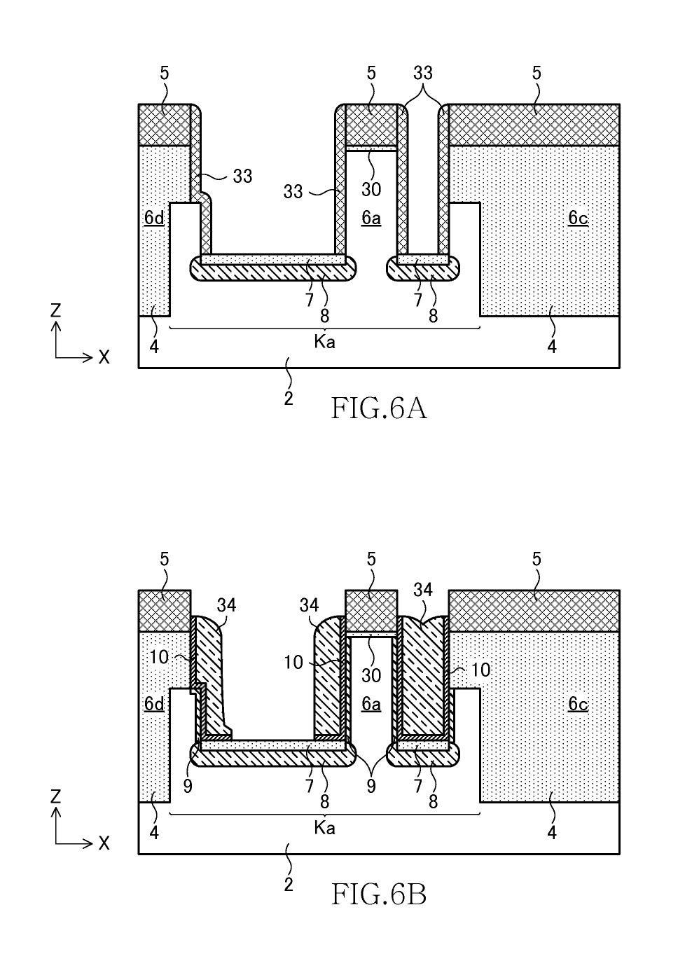

Next, a silicon nitride film having a thickness of, e.g., 10 nm is formed on the entire surface. The silicon nitride film is etched back by dry etching using fluorine-containing plasma to form a sidewall nitride film (silicon nitride film) 33 which covers the side surfaces of the pillars as shown in FIG. 6A. The sidewall nitride film 33 is formed in order to prevent n-type impurities to be ion-implanted in the next step from being implanted into the interiors of the pillars. A specific preferred method for forming the sidewall nitride film 33 includes low pressure chemical vapor deposition (LPCVD) using dichlorosilane (SiH₂Cl₂) and ammonia (NH₃) as material gases, under a condition of 750° C. in temperature and 60 Pa in pressure. Since silicon nitride films formed by LPCVD have excellent step coverage, it becomes possible to form a silicon nitride film of uniform thickness on the side surfaces of the pillars by using the above-mentioned method.

After the formation of the sidewall nitride film 33, the surface of the semiconductor substrate 2 exposed in the first and second active areas Ka and Kb is thermally oxidized to form a silicon oxide film 7 having a thickness of approximately 20 nm. Subsequently, n-type impurities such as phosphorus and arsenic are ion-implanted into the entire surface. After the implantation, the implanted impurities are activated by heat treatment of, e.g., 1000° C. for 10 seconds. As a result, lower diffusion layers 8, or n-type semiconductor regions, are formed in the surface of the semiconductor substrate 2 immediately below the silicon oxide film 7. Specifically, the lower diffusion layers 8 are preferred to have an impurity concentration of 10²⁰ to 10²¹ atoms/cm³, for example.

After the end of the ion implantation, the entire article is immersed into a phosphoric acid solution heated to, e.g., 150° C. to remove the sidewall nitride film 33. Here, the silicon nitride film 5 is also etched by approximately 10 nm from the top. However, since the silicon nitride film 5 has been formed to a thickness of 100 nm as described above, a sufficient thickness of silicon nitride film 5 remains after the end of the immersion.

Next, the exposed surfaces of the semiconductor substrate 2 are thermally oxidized to form a gate insulation film 9 made of a silicon oxide film on the side surfaces of the pillars as shown in FIG. 6B. The gate insulation film 9 preferably has a thickness of 5 nm. A barrier layer 10 made of titanium (Ti) and titanium nitride (TiN) and an amorphous silicon film 34 containing 5×10²⁰ atoms/cm³ of phosphorus are successively deposited on the entire surface by LPCVD. The amorphous silicon film 34 preferably has a thickness of 5 to 20 nm. The barrier layer 10 and the amorphous silicon film 34 are preferably formed by using monosilane (SiH₄) pure gas or a mixed gas of disilane (Si₂H₆) and phosphine (PH₃) as a material gas, under a condition of 530° C. in temperature and 60 Pa in pressure.

Next, the entire surface of the amorphous silicon film 34 and the barrier layer 10 is etched back by dry etching using plasma that contains bromine, chlorine, and oxygen. As a result, as shown in FIG. 6B, sidewalls made of the amorphous silicon film 34 and the barrier layer 10 are left on the side surfaces of the pillars. The amount of etching here is adjusted so that the top ends of the remaining amorphous silicon film 34 come between the top surface of the silicon nitride film 5 and the top surface of the pad oxide film 30. If the top ends of the amorphous silicon film 35 lie below the top surface of the pad oxide film 30, the gate insulator film 9 lying at the top edges of the first and second semiconductor pillars 6a and 6b can be exposed during the etch-back, and unfavorably etched off in a subsequent cleaning step.

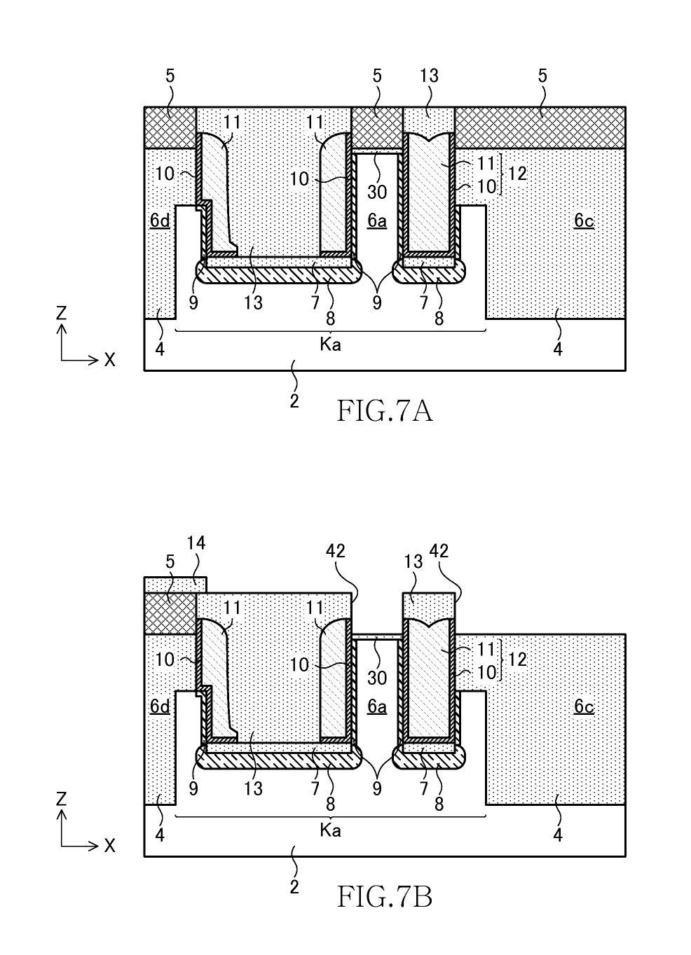

Next, a heat treatment of, e.g., 1000° C. is performed for 10 seconds to transform the amorphous silicon film 34 into a polycrystalline silicon film (polysilicon film 11) as shown in FIG. 7A. The heat treatment also activates the phosphor impurities included in the polysilicon film 11. As a result, the polysilicon film 11 becomes an impurity-doped silicon film which is a conductor. The gate electrode 12 including the polysilicon film 11 and the barrier layer 10 is completed by the steps so far.

A planar arrangement of the first and second semiconductor pillars 6a and 6b will be described. As mentioned above, the gate electrode 12 is formed on the side surfaces of the first and second semiconductor pillars 6a and 6b and the insulator pillar 6c. Such portions of the gate electrode 12 need to be integrally formed. The method for manufacturing the semiconductor device 1 according to the present embodiment achieves the integral formation by configuring the distances between the respective first and second semiconductor pillars 6a and 6b and the insulator pillar 6c to be no greater than twice the lateral thickness (the thickness of the portions formed on the side surfaces of the pillars) of the stacked film of the amorphous silicon film 34 and the barrier layer 10. This integrates the amorphous silicon film 34 deposited on the side surfaces of the insulator pillar 6c with the amorphous silicon film 34 deposited on the side surfaces of the first and second semiconductor pillars 6a and 6b. As a result, the gate electrodes 12 formed on the side surfaces of the first and second semiconductor pillars 6a and 6b and the side surface of the insulator pillar 6c can be integrated.

Next, a silicon oxide film is deposited by spin coating to a thickness such that the silicon nitride film 5 is covered over. The surface of the silicon oxide film is flattened until the top surface of the silicon nitride film 5 is exposed. A chemical mechanical polishing (CMP) technique is suitably used for the flattening. The silicon nitride film 5 here functions as a CMP stopper film. Consequently, as shown in FIG. 7A, an interlayer insulation film 13 (second interlayer insulation film) having a top surface at the same height as the top surface of the silicon nitride film 5 is formed.

Next, a silicon oxide film is formed by CVD. The silicon oxide film is pattered by lithography and dry etching to form a mask silicon oxide film 14 on the top surface of the insulator pillar 6d as shown in FIG. 7B. The mask silicon oxide film 14, as shown in FIG. 7B, is preferably formed to protrude somewhat from the top surface of the insulator pillar 6d. The protrusion can secure the silicon nitride film 5 formed on the top surface of the insulator pillar 6d from the etching of a silicon nitride film in the next step.

After the formation of the mask silicon oxide film 14, the entire article is immersed into a phosphoric acid solution heated to, e.g., 150° C., whereby portions of the silicon nitride film 5 formed on the top surfaces of the first and second semiconductor pillars 6a and 6b and the insulator pillar 6c are removed. This forms openings 42 (first and second openings) above the top surfaces of the first and second semiconductor pillars 6a and 6b and the insulator pillar 6c. The interlayer insulation film 13 and the gate electrode 12 are exposed in the inside walls of the openings 42. The pad oxide film 30 and the silicon oxide film 4 are exposed at the bottoms of the openings 42. After the formation of the openings 42, the pad oxide film 30 is removed by using a fluorine-containing solution to expose the top surfaces of the first and second semiconductor pillars 6a and 6b.

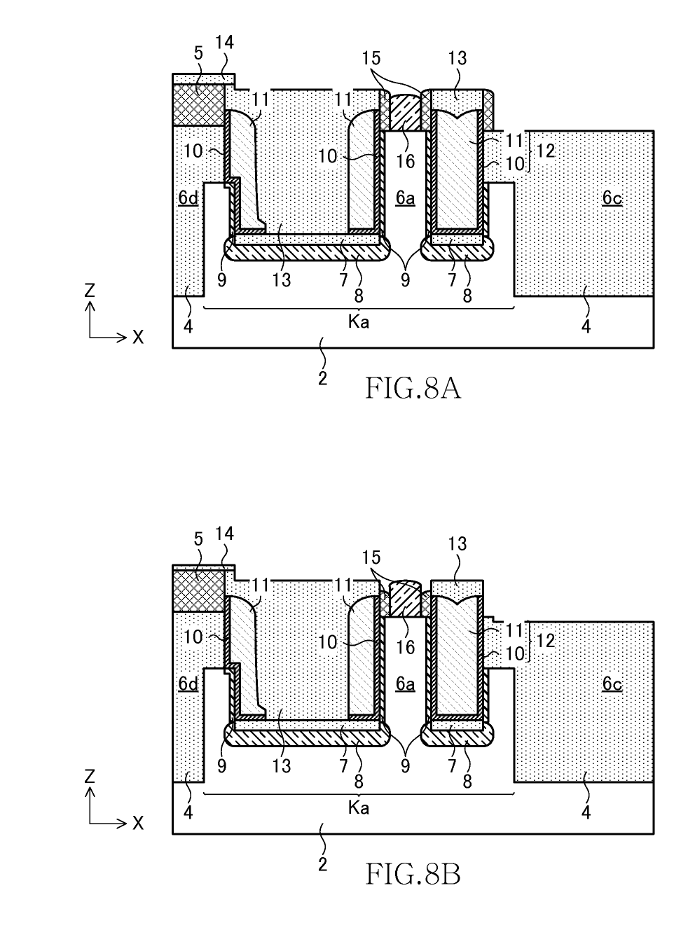

Next, a silicon nitride film having a thickness of, e.g., 10 nm is formed on the entire surface by LPCVD. The entire surface of the silicon nitride film is etched back by dry etching to form a sidewall-like silicon nitride film 15 on the inside walls of the openings 42 as shown in FIG. 8A. An upper diffusion layer 16 is then formed on the exposed surfaces of the semiconductor substrate 2 (the top surfaces of the first and second semiconductor pillars 6a and 6b). The upper diffusion layer 16 is an n-type monocrystalline silicon layer containing phosphorus as an impurity. As shown in FIG. 8A, the thickness of the upper diffusion layer 16 is set so that the top surface of the upper diffusion layer 16 lies below the top surface of the interlayer insulation film 13. The upper diffusion layer 16 has an impurity concentration of 10²⁰ to 10²¹ atoms/cm³.

A specific preferred method for forming the upper diffusion layer 16 is a selective epitaxial growth method. The selective epitaxial growth method includes growing silicon by using crystals exposed in the surface of the monocrystalline silicon constituting the semiconductor substrate 2 as a seed. The grown silicon film is thus naturally monocrystalline. A specific growth condition includes a temperature range of 750° C. to 900° C. in a hydrogen atmosphere below the atmospheric pressure. Dichlorosilane (SiH₂Cl₂), hydrogen chloride (HCl), and phosphine (PH₃) are preferably used as material gas. The material gas contains phosphine (PH₃) in order to introduce phosphorus into the upper diffusion layer 16. The upper diffusion layer 16 generated by such a method becomes monocrystalline and electrically conductive in the deposition stage. No heat treatment is thus needed to activate impurities.

The upper diffusion layer 16 may be made of polycrystalline silicon. In such a case, the upper diffusion layer 16 can be formed by the same way as described above but in a mixed atmosphere of hydrogen and nitrogen instead of the hydrogen atmosphere. Since the atmosphere contains nitrogen, crystals exposed in the exposed surfaces of the semiconductor substrate 2 are terminated with nitrogen and no longer function as a seed. As a result, polycrystalline silicon is formed without epitaxial growth. Even polycrystalline silicon can be selectively formed only on the exposed surfaces of the semiconductor substrate 2. If the upper diffusion layer 16 is made of monocrystalline silicon, crystals appearing at the top make the surface of the upper diffusion layer 16 irregular. In contrast, if the upper diffusion layer 16 is made of polycrystalline silicon, such irregularities are extremely small. The upper diffusion layer 16 can thus be formed with a smoother surface.

The impurities need not be introduced during deposition. Instead, a non-doped silicon film may be formed by selective epitaxial growth before impurities such as phosphorus and arsenic are introduced by ion implantation. In such a case, a heat treatment for activating the impurities is needed after the ion implantation.

Next, the entire article is immersed into a phosphoric acid solution heated to, e.g., 150° C. to remove the silicon nitride film 15. As shown in FIG. 8B, the silicon nitride film 15 formed on the top surface of the insulator pillar 6c is thus completely removed. Meanwhile, the silicon nitride film 15 formed on the top surfaces of the first and second semiconductor pillars 6a and 6b is not completely removed but only recessed by 20 nm or so. The reason is that the presence of the upper diffusion layer 16 hinders the movement of the phosphoric acid solution. The remaining silicon nitride film 15 ensures insulation between the gate electrode 12 and the upper diffusion layer 16.

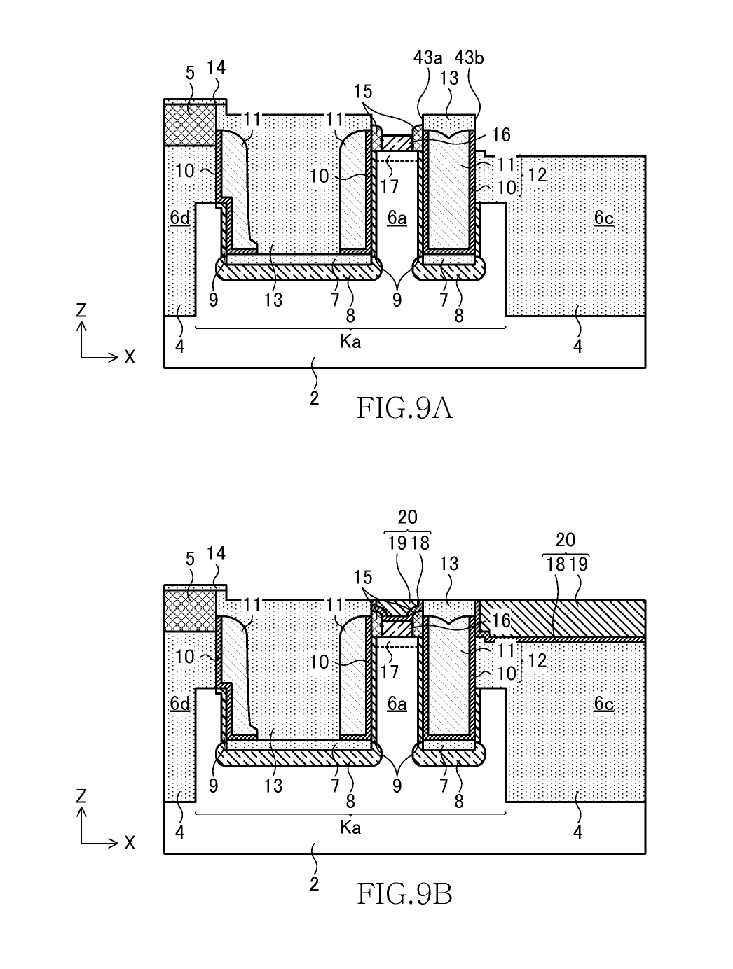

Next, as shown in FIG. 9A, the upper diffusion layer 16 is etched back by approximately 40 nm. Subsequently, phosphorus is ion-implanted into the entire surface, whereby an LDD diffusion layer 17 is formed in the top ends of the first and second semiconductor pillars 6a and 6b. The LDD diffusion layer 17 preferably has an impurity concentration of 10¹⁸ to 10¹⁹ atoms/cm³. By the steps so far, openings 43a where the upper diffusion layer 16 and the top surface of the silicon nitride film 15 are exposed at the bottom are formed above the first and second semiconductor pillars 6a and 6b. Similarly, an opening 43b where the top surface of the insulator pillar 6c is exposed at the bottom is formed above the insulator pillar 6c.

Next, titanium (Ti), titanium nitride (TiN), and tungsten (W) are successively deposited on the entire surface by CVD. The titanium nitride (TiN) and titanium (Ti) constitute the barrier layer 18 shown in FIG. 9B. The titanium nitride (TiN) and titanium (Ti) are each formed in a thickness such that the barrier layer 18 will not fill up the interiors of the openings 43a and 43b. The tungsten (W) constitutes the tungsten film 19 shown in FIG. 9B, and is deposited in a thickness such as to fill up the openings 43a and 43b. After the completion of the deposition of tungsten (W), the Ti/TiN/W stacked film formed on the top surfaces of the interlayer insulation film 13 and the mask silicon oxide film 14 is removed by CMP. Consequently, as shown in FIG. 9B, a conductive film 20 made of a Ti/TiN/W stacked film is formed in the openings 43a and 43b. The LDD diffusion layer 17, the upper diffusion layer 16, and the conductive film 20 in the opening 43a function as a pillar upper electrode layer formed on the top of the semiconductor pillar. The conductive film 20 formed on the insulator pillar 6c and the conductive film 20 formed on the insulator pillars 6a and 6b have approximately the same height when measured from the back surface of the semiconductor substrate which is on the opposite side to the main surface of the semiconductor substrate.

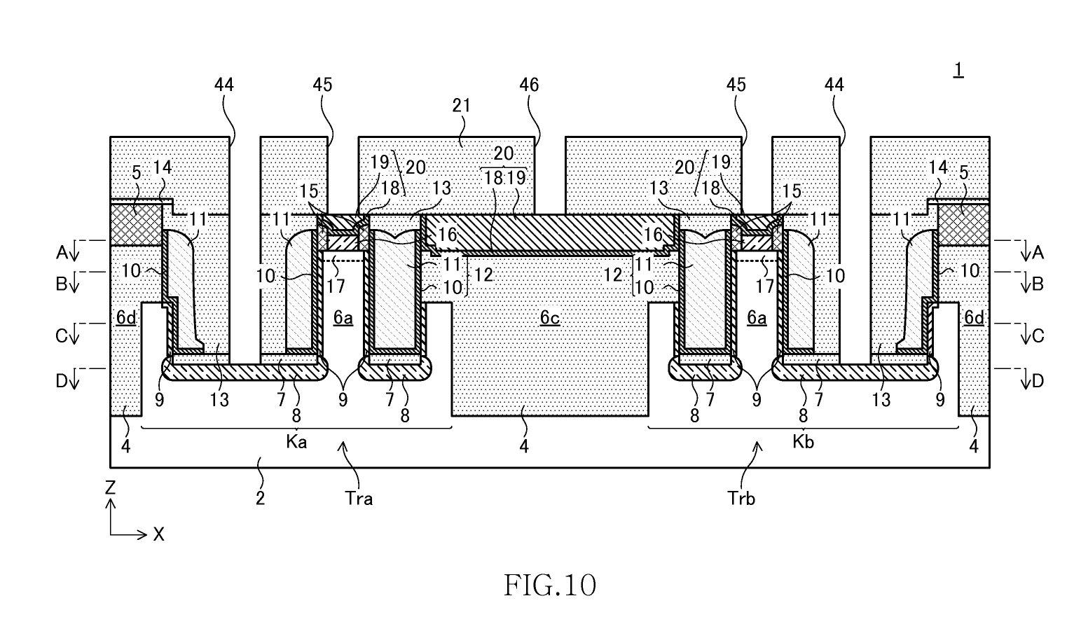

Next, a silicon oxide film is deposited on the entire surface by CVD or spin coating. The surface is flattened by CMP to form an interlayer insulation film 21 (first interlayer insulation film) covering the entire surface as shown in FIG. 10. The interlayer insulation film 21 may have a thickness of 80 nm, for example. The interlayer insulation films 21 and 13 and the silicon oxide film 7 are then etched by lithography and dry etching to form contact holes 44 to 46. The contact holes 44 are formed in the first and second active regions Ka and Kb on a one-on-one basis. The contact holes 44 are formed through the interlayer insulation films 21 and 13 and the silicon oxide film 7 in areas where none of the pillars 6a to 6d and the gate electrode 12 is formed. The lower diffusion layer 8 is exposed at the bottoms of the contact holes 44. The contract holes 45 are formed in the first and second active regions Ka and Kb on a one-on-one basis. The contact holes 45 are formed through the interlayer insulation film 21 lying immediately above the respective corresponding semiconductor pillars. The conductive film 20 formed on the top surface of the upper diffusion layer 16 is exposed at the bottoms of the contact holes 45. The single contact hole 46 is formed through the interlayer insulation film 21 lying immediately above the insulator pillar 6c. The conductive film 20 formed on the top surface of the insulator pillar 6c is exposed at the bottom of the contact hole 46.

After the formation of the contact holes 44 to 46, a cobalt film is deposited on the entire surface by sputtering, followed by heat treatment at a temperature of 500° C. to 800° C. As a result, the deposited cobalt film reacts with silicon constituting the lower diffusion layer 8 at the bottoms of the contact holes 44, thereby being transformed into the cobalt silicide film 22c shown in FIG. 1. In other locations, the cobalt film is not transformed into a cobalt silicide film. After the end of the heat treatment, the unreacted cobalt film formed in the other locations is removed by a sulfuric acid solution.

Cobalt silicide films have the effect of reducing a contact resistance between silicon and a metal film. The provision of the cobalt silicide film 22c between the barrier layer 22b, which is a metal layer, and the lower diffusion layer 8 can thus reduce the resistance of the lower diffusion layer contact plugs 22.

Next, titanium (Ti), titanium nitride (TiN), and tungsten (W) are successively deposited on the entire surface by CVD. The titanium nitride (TiN) and titanium (Ti) constitute the barrier layers 22b, 23b, and 24b shown in FIG. 1. The titanium nitride (TiN) and titanium (Ti) are each deposited in an extremely small thickness. The tungsten (W) constitutes the tungsten films 22a, 23a, and 24a shown in FIG. 1. The tungsten (W) is deposited in a thickness such as to fill up the contact holes 44 to 46. The contact resistance between the titanium nitride (TiN) and the cobalt silicide film 22c is relatively high, whereas the interposition of the titanium (Ti) can maintain the low resistance of the lower diffusion layer contact plugs 22.

After the completion of the deposition of tungsten (W), the Ti/TiN/W stacked film formed on the top surface of the interlayer insulation film 21 is removed by CMP. As a result, the lower diffusion layer contact plugs 22, the upper diffusion layer contact plugs 23, and the gate contact plug 24 shown in FIG. 1 are formed. Subsequently, the wiring pattern 25 is formed on the surface of the interlayer diffusion film 21 to complete the semiconductor device 1.

As has been described above, according to the method for manufacturing a semiconductor device of the present embodiment, the semiconductor device 1 having the conductive film 20 electrically connected to the gate electrode 12 and located on the top surface of the insulator pillar 6c can be manufactured. This can provide a gate electrode having a low wiring resistance as compared to when the conductive film 20 is not formed.

The contact hole 46 can be made with plenty of margin in positional control. The contact resistance between the gate contact plug 24 and the gate electrode 12 can also be reduced. In addition, the formation of the barrier layer 22b and the cobalt silicide film 22c in the lower portions of the lower diffusion layer contact plugs 22 can reduce the resistance of the lower diffusion layer contact plugs 22.

In the foregoing embodiment, the conductive film 20 and the gate electrode 12 are configured to make contact with each other around the entire circumference of the top surface of the insulator pillar 6c. However, the conductive film 20 and the gate electrode 12 may be configured to make contact with each other only in part of the circumference of the top surface of the insulator pillar 6c. In terms of reducing the contact resistance, the configuration with the all-around contact as in the foregoing embodiment is preferred.

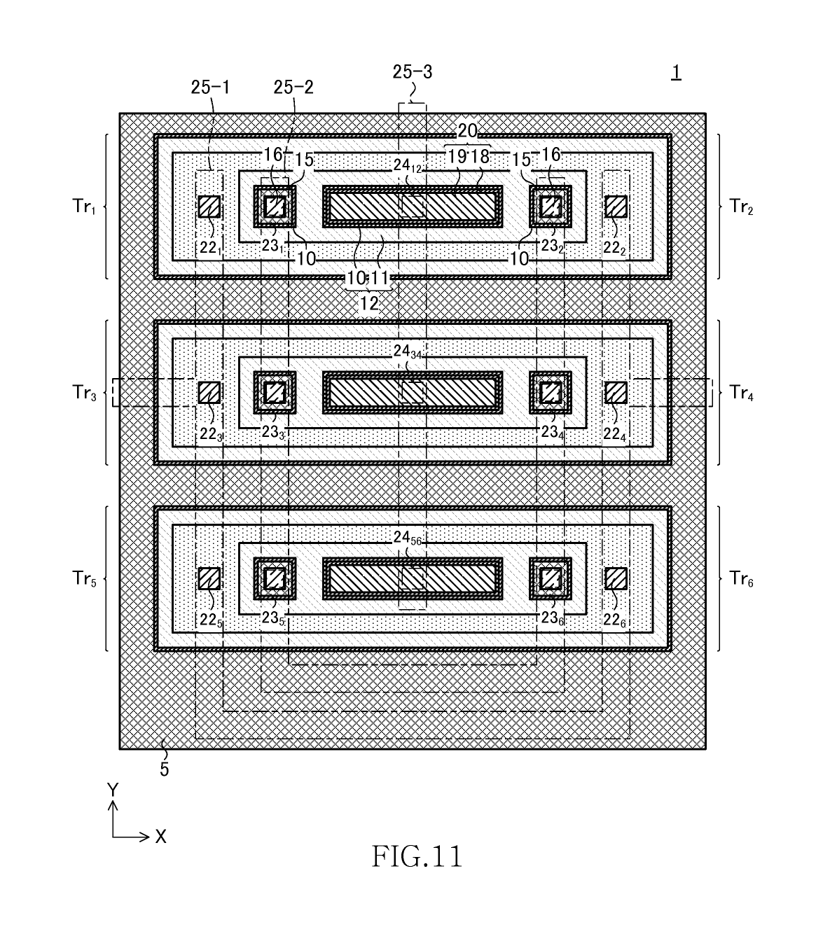

FIG. 11 shows a sectional view of the semiconductor device 1 according to the second embodiment of the present invention, taken along a plane corresponding to the line A-A of FIG. 1. FIG. 11 also shows a planar arrangement of upper diffusion layer contact plugs 23, gate contact plugs 24, and wiring traces 25-1 to 25-3.

As shown in FIG. 11, the semiconductor device 1 according to the present embodiment includes transistors Tr₁ to Tr₆ and the wiring traces 25-1 to 25-3 which connect the transistors Tr₁ to Tr₆. The transistors Tr₁ and Tr₂ have the same structure as that of the transistors Tra and Trb described in the first embodiment. Similarly, the transistors Tr₃ and Tr₄ and the transistors Tr₅ and Tr₆ both have the same structure as that of the transistors Tra and Trb described in the first embodiment. In the following description, the suffixes “1” to “6” attached to the reference symbols of components represent that the components are ones corresponding to the transistors Tr₁ to Tr₆, respectively. The suffix “12” attached to the reference symbol of a component represents that the component is one common to the transistors Tr₁ and Tr₂. The same applies to the suffixes “34” and “56” attached to the reference symbols of components.

The transistors Tr₁ to Tr₆ are arranged so that the transistors Tr₁, Tr₃, and Tr₅ are in a row in a Y direction, and the transistors Tr₂, Tr₄, and Tr₆ are in a row in the Y direction. As shown in FIG. 11, the contact plugs of the transistors Tr₁ to Tr₆ are thereby aligned in the Y direction. Specifically, a row of lower diffusion layer contact plugs 22₁, 22₃, and 22₅, a row of upper diffusion layer contact plugs 23₁, 23₃, and 23₅, a row of gate contact plugs 24₁₂, 24₃₄, and 24₅₆, a row of upper diffusion layer contact plugs 23₂, 23₄, and 23₆, and a row of lower diffusion layer contact plugs 22₂, 22₄, and 22₆ are arranged in order from one side of the X direction (left in the diagram).

The wiring trace 25-1 is a U-shaped wiring trace having two leg portions each extending in the Y direction. One of the leg portions is connected to the lower diffusion layer contact plugs 22₁, 22₃, and 22₅. The other leg portion is connected to the lower diffusion layer contact plugs 22₂, 22₄, and 22₆. The two leg portions are connected to each other above the silicon nitride film 5 (above the insulator pillar 6d shown in FIG. 1).

Similarly, the wiring trace 25-2 is a U-shaped wiring trace having two leg portions each extending in the Y direction. One of the leg portions is connected to the upper diffusion layer contact plugs 23₁, 23₃, and 23₅. The other leg portion is connected to the upper diffusion layer contact plugs 23₂, 23₄, and 23₆. The two leg portions are connected to each other above the silicon nitride film 5 (above the insulator pillar 6d shown in FIG. 1).

The wiring trace 25-3 is a straight wiring trace extending in the Y direction. The wiring trace 25-3 is connected to the gate contract plugs 24₁₂, 24₃₄, and 24₅₆.

With the foregoing configuration, the transistors Tr₁ to Tr₆ are connected in parallel between the wiring trace 25-1 and the wiring trace 25-2. A common potential is supplied to the gate electrodes 12 of the transistors Tr₁ to Tr₆ through the wiring trace 25-3. In other words, the transistors Tr₁ to Tr₆ operate as a single transistor having a gate width six times that of each transistor.

As described in the first embodiment, the structure of the transistors Tr₁ to Tr₆ according to the present embodiment reduces the contact resistances between the gate contact plugs 24 and the gate electrodes 12 and the resistances of the lower diffusion layer contact plugs 22. This reduces the delay of signals that pass through such components. The conductive films 20 are made of a metal material (tungsten films 19), which reduces a delay occurring in the conductive films 20. In the semiconductor device 1 according to the present embodiment, the six transistors Tr₁ to Tr₆ need to be connected to each other. The wiring traces 25-1 to 25-3 thus have an extremely large wiring length, which increases a signal delay in such portions. Under the circumstances, the reduction of the signal delay by virtue of the structure of the transistors Tr₁ to Tr₆ according to the present embodiment increases its significance.

As has been described above, according to the semiconductor device 1 of the present embodiment, the structure of the present invention can be applied to each of three or more transistors connected in parallel to provide the effects described in the first embodiment. As the wiring length increases, the effect of reducing a signal delay becomes more significant.

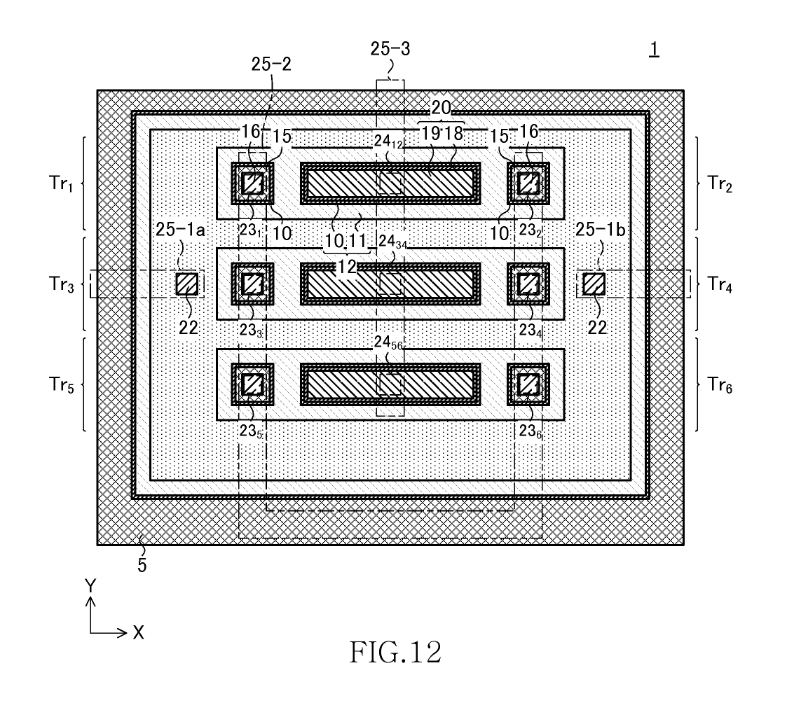

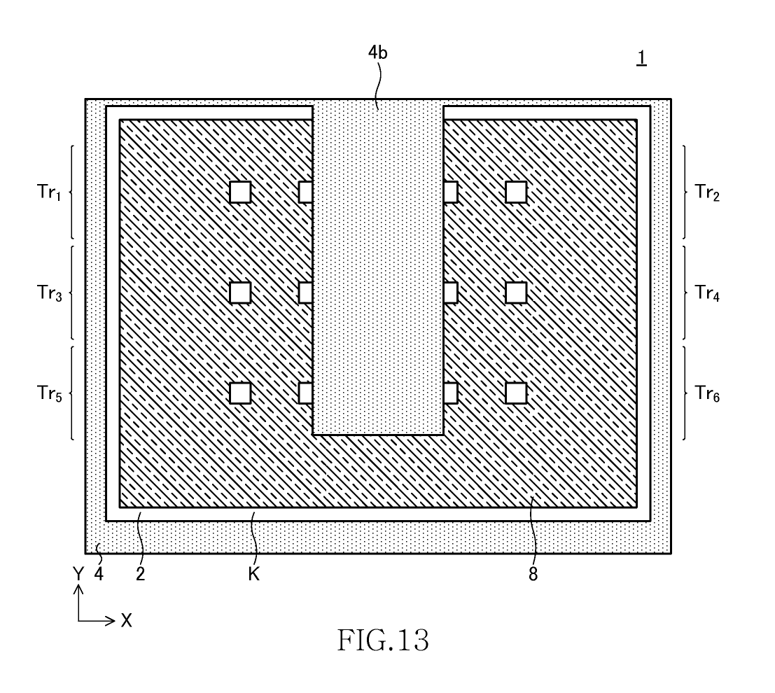

FIG. 12 shows a sectional view of the semiconductor device 1 according to the third embodiment of the present invention, taken along a plane corresponding to the line A-A of FIG. 1. FIG. 12 also shows a planar arrangement of upper diffusion layer contact plugs 23, gate contact plugs 24, and wiring traces 25-1a, 25-1b, 25-2, and 25-3. FIG. 13 shows a sectional view of the semiconductor device 1 according to the present embodiment, taken along a plane corresponding to the line D-D of FIG. 1.

As shown in FIGS. 12 and 13, the semiconductor device 1 according to the present embodiment includes transistors Tr₁ to Tr₆ and the wiring traces 25-1a, 25-1b, 25-2, and 25-3 which connect the transistors Tr₁ to Tr₆. The structures and arrangement of the transistors and the shapes and arrangement of the wiring traces are similar to those described in the second embodiment. Differences lie in that the active regions are made common, that two lower diffusion layer contact plugs 22 are provided for the transistors Tr₁ to Tr₆ in common, and that the wiring trace 25-1 is divided into the two wiring traces 25-1a and 25-1b. The following description mainly deals with the differences.

As shown in FIG. 13, in the semiconductor device 1 according to the present embodiment, the transistors Tr₁ to Tr₆ are formed in a single active region K (third active region). The active region K has a U shape including two leg portions. A silicon oxide film 4b is formed in the area between the leg portions. The silicon oxide film 4b is a part of the silicon oxide film 4. The silicon oxide film 4b is utilized to form the insulator pillar 6c shown in FIG. 1. In FIG. 12, insulator pillars 6c are formed in areas overlapping with the conductive films 20 when seen in a plan view.

Specifically, the transistors Tr₁, Tr₃, and Tr₅ are arranged on one side in the X direction of the silicon oxide film 4b which is long in the Y direction. The transistors Tr₂, Tr₄, and Tr₆ are arranged on the other side in the X direction. The insulator pillar 6c corresponding to the transistors Tr₁ and Tr₂, the insulator pillar 6c corresponding to the transistors Tr₃ and Tr₄, and the insulator pillar 6c corresponding to the transistors Tr₅ and Tr₆ are formed on the interposed silicon oxide film 4b.

A lower diffusion layer 8 is formed on the surface of the semiconductor device 2 inside the active region K, in areas where none of the semiconductor pillars and the insulator pillars is formed. Since the active region K is common to the transistors Tr₁ to Tr₆, the lower diffusion layer 8 is also common to the transistors Tr₁ to Tr₆ as shown in FIG. 13.

As shown in FIG. 12, there are provided only two lower diffusion layer contact plugs 22. One of the lower diffusion layer contact plugs 22 is arranged near the transistor Tr₃ and connected to the wiring trace 25-1a. The other lower diffusion layer contact plugs 22 is arranged near the transistor Tr₄ and connected to the wiring trace 25-1b. Since the lower diffusion layer 8 extends over the entire area, the two lower diffusion layer contact plugs 22 are short-circuited, and the same operation is obtained electrically by using either one of the lower diffusion layer contact plugs 22. The configuration of the upper electrode contact plugs 23₁ to 23₆ and the wiring trace 25-2, and the configuration of the gate contact plugs 24₁₂, 24₃₄, and 24₅₆ and the wiring trace 25-3 are the same as in the second embodiment. Consequently, the transistors Tr₁ to Tr₆ according to the present embodiment are connected in parallel between the wiring trace 25-1a (or wiring trace 25-1b) and the wiring trace 25-2.

As has been described above, according to the semiconductor device 1 of the present embodiment, the structure of the present invention can be applied to each of three or more transistors that have a common active region and are connected in parallel. As a result, the effects described in the first embodiment can be obtained.

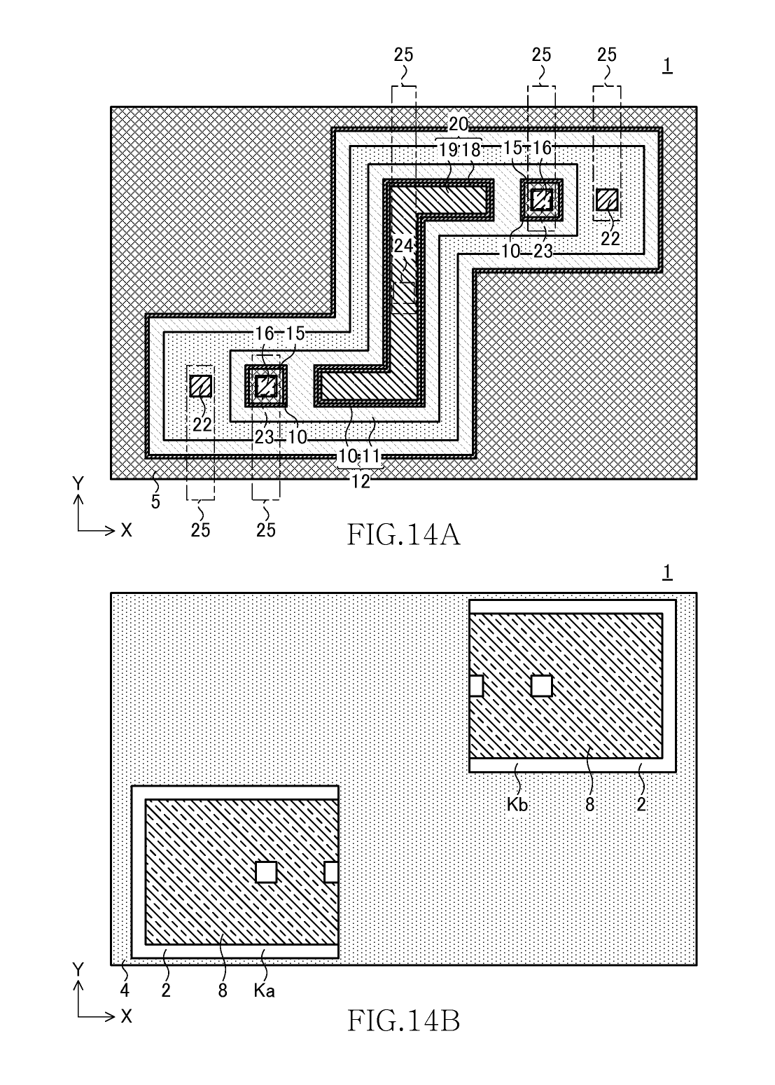

FIG. 14A shows a sectional view of the semiconductor device 1 according to the fourth embodiment of the present invention, taken along a plane corresponding to the line A-A of FIG. 1. FIG. 14A also shows a planar arrangement of upper diffusion layer contact plugs 23, a gate contact plug 24, and wiring pattern 25. FIG. 14B shows a sectional view of the semiconductor device 1 according to the present embodiment, taken along a plane corresponding to the line D-D of FIG. 1.

As shown in FIGS. 14A and 14B, the semiconductor device 1 according to the present embodiment differs from the first embodiment in that the conductive film 20 and the insulator pillar 6c immediately below (FIG. 1) have an S shape, being bent at right angles in two locations. In other respects, the semiconductor device 1 according to the present embodiment is the same as the first embodiment.

In the present embodiment, the S-shaped arrangement of the insulator pillar 6c increases the wiring length of the gate electrode 12 as compared to the first embodiment. As the use of vertical transistors becomes more common, transistors formed in arbitrary positions will need to be connected by a long gate electrode 12 as in this example. In such a case, to reduce the wiring resistance of the gate electrode 12 becomes vitally important. The semiconductor device 1 according to the present embodiment includes the conductive film 20 described in the first embodiment. This can suppress an increase in the wiring resistance due to the increased length of the gate electrode 12.

If there is no conductive film 20, a signal input through the gate contact plug 24 is transmitted to the semiconductor pillars mainly via the polysilicon that constitutes the gate electrode 12. In such a case, a signal delay increases as the gate electrode 12 becomes longer. According to the present embodiment, the signal is transmitted through the metal material (tungsten film 19) constituting the conductive film 20. This can suppress an increase of the signal delay due to the increased length of the gate electrode 12.

As has been described above, according to the semiconductor device 1 of the present embodiment, even if the gate electrode 12 common to two transistors increases in length, a resulting increase in the wiring resistance and an increase of the signal delay can be suppressed.

It is apparent that the present invention is not limited to the above embodiments, but may be modified and changed without departing from the scope and spirit of the invention.

For example, the foregoing embodiments have dealt with the cases where an insulator pillar 6c is arranged between two vertical transistors, and the conductive film 20 is formed on the top surface of the insulator pillar 6c. However, the present invention may be applied to a single vertical transistor. Even in such a case, the foregoing effects can be obtained by forming an insulator pillar for constituting an extended gate electrode, and forming a conductive film on the top surface of the insulator pillar.

What is claimed is:

1. A semiconductor device comprising:
a semiconductor substrate having a main surface;
a first semiconductor pillar having a side surface that is substantially perpendicular to the main surface of the semiconductor substrate;
an insulator pillar having a side surface that is substantially perpendicular to the main surface of the semiconductor substrate and a top surface that is substantially parallel to the main surface of the semiconductor substrate;
a first gate electrode covering the side surface of the first semiconductor pillar with an intervention of a first gate insulation film;
an extended gate electrode covering the side surface of the insulator pillar, the extended gate electrode being contacted with the first gate electrode; and
a conductive film formed on the top surface of the insulator pillar, the conductive film being in contact with the extended gate electrode in a position above the top surface of the insulator pillar.

2. The semiconductor device as claimed in claim 1, wherein the conductive film comprises a metal material.

3. The semiconductor device as claimed in claim 2, wherein the conductive film comprises a stacked film having a first barrier layer and the metal material stacked on the first barrier layer.

4. The semiconductor device as claimed in claim 2, wherein the metal material comprises tungsten.

5. The semiconductor device as claimed in claim 1, wherein the conductive film is lower in resistivity than an impurity-doped silicon film.

6. The semiconductor device as claimed in claim 1, wherein the conductive film is configured to be in contact with the extended gate electrode around an entire circumference of the top surface of the insulator pillar.

7. The semiconductor device as claimed in claim 1, wherein each of the first gate electrode and the extended gate electrode comprises a stacked film having a second barrier layer and a polysilicon stacked on the second barrier layer.

8. The semiconductor device as claimed in claim 1, further comprising:
an interlayer insulation film formed on the main surface of the semiconductor substrate so as to cover the first semiconductor pillar, the insulator pillar, the first gate electrode, the extended gate electrode, and the conductive film;
a lower diffusion layer formed in contact with a lower portion of the first semiconductor pillar;
an upper diffusion layer formed in contact with an upper portion of the first semiconductor pillar;
a first contact plug penetrating through the interlayer insulation film and electrically connected to the lower diffusion layer;
a second contact plug penetrating through the interlayer insulation film and electrically connected to the upper diffusion layer; and
a third contact plug penetrating through the interlayer insulation film to contact with at least either one of the extended gate electrode and the conductive film.

9. The semiconductor device as claimed in claim 8, wherein
the conductive film is also formed on a top surface of the upper diffusion layer, and
the second contact plug is in electrical contact with the upper diffusion layer through the conductive film.

10. The semiconductor device as claimed in claim 8, wherein the first contact plug includes a cobalt silicide film, and is in contact with the lower diffusion layer through the cobalt silicide film.

11. The semiconductor device as claimed in claim 1, further comprising:
a second semiconductor pillar having a side surface that is substantially perpendicular to the main surface of the semiconductor substrate; and
a second gate electrode covering the side surface of the second semiconductor pillar with an intervention of a second gate insulation film, wherein
the insulator pillar is arranged between the first and second semiconductor pillars, and
the extended gate electrode is contacted with the first and second gate electrodes.

12. The semiconductor device as claimed in claim 11, wherein
the main surface of the semiconductor substrate includes first and second active regions that are defined by respective element isolation regions,
the first semiconductor pillar is formed in the first active region, and
the second semiconductor pillar is formed in the second active region.

13. The semiconductor device as claimed in claim 11, wherein
the main surface of the semiconductor substrate includes a third active region that is defined by an element isolation region, and
the first and second semiconductor pillars are both formed in the third active region.

14. The semiconductor device as claimed in claim 7, wherein the second barrier layer is in direct contact with the first barrier layer.

15. The semiconductor device as claimed in claim 8, wherein the upper diffusion layer is electrically isolated from the first gate electrode and the extended gate electrode by a sidewall insulation film.

16. The semiconductor device as claimed in claim 9, wherein
the conductive film formed on the top surface of the insulator pillar has a first top surface,
the conductive film formed on the top surface of the upper diffusion layer has a second top surface, and
the first and second top surfaces are substantially coplanar.

17. The semiconductor device as claimed in claim 9, wherein the conductive film formed on the top surface of the upper diffusion layer and the conductive film formed on the top surface of the insulator pillar are made of the same material.

18. The semiconductor device as claimed in claim 11, wherein
the first semiconductor pillar and the insulator pillar are arranged on a first straight line, and
the second semiconductor pillar and the insulator pillar are arranged on a second straight line different from the first straight line.

19. A semiconductor device comprising:
a semiconductor substrate having a main surface;
a plurality of first semiconductor pillars arranged in a first direction, each of the first semiconductor pillars having a side surface that is substantially perpendicular to the main surface of the semiconductor substrate;
a plurality of second semiconductor pillars arranged in the first direction, each of the second semiconductor pillars having a side surface that is substantially perpendicular to the main surface of the semiconductor substrate;
a plurality of insulator pillars each arranged between an associated one of the first semiconductor pillars and an associated one of the second semiconductor pillars, each of the insulator pillars having a side surface that is substantially perpendicular to the main surface of the semiconductor substrate and a top surface that is substantially parallel to the main surface of the semiconductor substrate;
a plurality of first gate electrodes each covering the side surface of each of the first semiconductor pillars with an intervention of a first gate insulation film;
a plurality of second gate electrodes each covering the side surface of each of the second semiconductor pillars with an intervention of a second gate insulation film;
a plurality of extended gate electrodes each covering the side surface of each of the insulator pillars, the extended gate electrode being contacted with the first and second gate electrodes;
a plurality of conductive films each formed on the top surface of an associated one of the insulator pillars, the conductive films being in contact with the extended gate electrode in a position above the top surface of each of the insulator pillars;
a plurality of first upper diffusion layers each formed in contact with an upper portion of an associated one of the first semiconductor pillars;
a plurality of second upper diffusion layers each formed in contact with an upper portion of an associated one of the second semiconductor pillars;
a first wiring extending in the first direction and connected in common to the first upper diffusion layers;
a second wiring extending in the first direction and connected in common to the second upper diffusion layers;
a third wiring connected between the first and second wirings; and
a fourth wiring extending in the first direction and connected in common to the conductive films.

20. The semiconductor device as claimed in claim 19, wherein
the main surface of the semiconductor substrate includes an active region defined by an element isolation region, and
the first and second semiconductor pillars are both formed in the active region.
